(19) United States
(12) Patent Application Publication
(10) Pub. No.: US 2025/0234714 A1
(43) Pub. Date: Jul. 17, 2025

(54) DISPLAY DEVICE AND METHOD OF FABRICATING DISPLAY DEVICE

(71) Applicant: Samsung Display Co., LTD., Yongin-si (KR)

(72) Inventors: Hyun Eok SHIN, Yongin-si (KR); Joon Yong PARK, Yongin-si (KR); Su Kyoung YANG, Yongin-si (KR); Dong Min LEE, Yongin-si (KR)

(21) Appl. No.: 18/818,567

(22) Filed: Aug. 28, 2024

(30) Foreign Application Priority Data
Jan. 16, 2024 (KR) 10-2024-0006688

(51) Int. Cl. H10K 59/122; H10K 59/12; H10K 59/80

(52) U.S. Cl. CPC H10K 59/122; H10K 59/1201; H10K 59/873

(57) ABSTRACT

A display device is provided. The display device includes a pixel electrode disposed on a substrate; a pixel defining layer disposed on an edge of the pixel electrode; a light emitting layer disposed on the pixel electrode; a common electrode disposed on the light emitting layer; a first bank disposed on the pixel defining layer and including a first side surface partially overlapping the common electrode and a second side surface opposite to the first side surface; and a second bank disposed on the first bank and including a first side surface adjacent to the common electrode and a second side surface opposite to the first side surface. The first side surface of the second bank protrudes more than the first side surface of the first bank, and the first side surface of the second bank is aligned with the second side surface of the first bank.

This application claims priority to Korean Patent Application No. 10-2024-0006688 filed on Jan. 16, 2024, and all the benefits accruing therefrom under 35 U.S.C. § 119, the content of which in its entirety is herein incorporated by reference.

### BACKGROUND

### 1. Technical Field

The present disclosure relates to a display device and a method of fabricating the display device.

### 2. Description of the Related Art

With the development of the information society, the demand for display devices of various forms for displaying an image is increasing. For example, display devices have been applied to various electronic devices such as, for example, smartphones, digital cameras, laptop computers, navigation devices, and smart televisions. Display devices may be flat panel display devices such as, for example, liquid crystal display devices, field emission display devices, or organic light emitting display devices. Among flat panel display devices, a light emitting display device may include a light emitting element in which each of the pixels of a display panel may emit light by itself, thereby displaying an image without a backlight unit providing the light to the display panel.

Recently, display devices have been applied to glasses-type devices to provide virtual reality and augmented reality. In some cases, in order for a display device to be applied to the glasses-type device, the display device is implemented in a very small size of two inches or less, but with a high pixel integration supportive of high resolution. For example, some display devices applied to a glasses-type device may have a high pixel integration of 400 pixels per inch (PPI) or more.

For cases in which the display device is implemented in a very small size but has high pixel integration as described above, it is difficult to implement light emitting elements separated for each light emitting area using a mask process because an area of a light emitting area where the light emitting elements are disposed is reduced.

### SUMMARY

Aspects of the present disclosure provide a display device capable of forming light emitting elements separated for each light emitting area without using a mask process.

Aspects of the present disclosure also provide a display device including a large light transmitting area.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

Details of other embodiments are included in the detailed description and drawings.

According to an embodiment of the present disclosure, a display device comprises a pixel electrode disposed on a substrate; a pixel defining layer disposed on an edge of the pixel electrode; a light emitting layer disposed on the pixel electrode; a common electrode disposed on the light emitting layer; a first bank disposed on the pixel defining layer and including a first side surface adjacent to the common electrode and a second side surface opposite to the first side surface; and a second bank disposed on the first bank and including a first side surface adjacent to the common electrode and a second side surface opposite to the first side surface, wherein the first side surface of the second bank protrudes more than the first side surface of the first bank, and the first side surface of the second bank is aligned with the second side surface of the first bank.

The substrate may include a light transmitting area and a display area surrounding the light transmitting area and including a light emitting area, the first side surface of the second bank may face the light emitting area, and the second side surface of the second bank may face the light transmitting area.

The pixel defining layer may include a first side surface and a second side surface opposite to the first side surface, the first side surface of the pixel defining layer may protrude more than the first side surface of the first bank, and the second side surface of the pixel defining layer may be aligned with the second side surface of the first bank.

The display device may further comprise a thin film transistor layer disposed between the pixel electrode and the substrate, wherein the thin film transistor layer may be exposed in the light transmitting area.

The display device may further comprise a thin film encapsulation layer disposed on the thin film transistor layer, the second bank, and the common electrode.

The thin film encapsulation layer may be in contact with the thin film transistor layer.

The display device may further comprise a first inorganic layer disposed on the common electrode and the first side surface of the first bank; and a second inorganic layer disposed on the second side surface of the first bank and the thin film transistor layer.

The first inorganic layer and the second inorganic layer may be spaced apart from an upper surface of the second bank.

The thin film encapsulation layer may include a lower inorganic encapsulation layer disposed on the common electrode, and an organic encapsulation layer disposed on the lower inorganic encapsulation layer, and the organic encapsulation layer may be in contact with the thin film transistor layer in the light transmitting area.

The thin film transistor layer may include a buffer layer, a gate insulating layer, an interlayer insulating layer, and a passivation layer sequentially disposed on the substrate, and the thin film encapsulation layer may be in contact with the passivation layer and the interlayer insulating layer.

The thin film encapsulation layer may include a lower inorganic encapsulation layer disposed on the common electrode; a reinforcement layer disposed on the lower inorganic encapsulation layer, the second bank, and the thin film transistor layer; and an organic encapsulation layer disposed on the reinforcement layer.

The common electrode may be in contact with the first side surface of the first bank.

The display device may further comprise an optical device overlapping the light transmitting area.

According to an embodiment of the present disclosure, a display device comprises a substrate including a light transmitting area and a display area surrounding the light transmitting area and including a light emitting area; a thin film transistor layer disposed on the substrate; a light emitting element disposed on the thin film transistor layer in the light emitting area; a first bank surrounding the light emitting element on the thin film transistor layer and including a first side surface facing the light emitting area and a second side surface facing the light transmitting area; and a second bank disposed on the first bank and including a first side surface facing the light emitting area and a second side surface facing the light transmitting area, wherein the first side surface of the second bank protrudes more than the first side surface of the first bank, and the second side surface of the second bank is aligned with the second side surface of the first bank.

The first bank and the second bank may overlap the display area and may not overlap the light transmitting area.

The light emitting element may include a pixel electrode, a light emitting layer, and a common electrode sequentially disposed on the thin film transistor layer, and one end of the common electrode may be in contact with the first side surface of the first bank.

According to an embodiment of the present disclosure, a method of fabricating a display device comprises forming a pixel electrode on a substrate, a sacrificial layer on the pixel electrode, a pixel defining material layer on the sacrificial layer and the substrate, a first bank material layer disposed on the pixel defining material layer, and a second bank material layer on the first bank material layer; forming a photoresist on the second bank material layer; and reducing a thickness of the photoresist in some areas.

The reducing of the thickness of the photoresist in some areas, a half tone exposure process may be used, and the second bank material layer not covered with the photoresist may be etched.

The method may further comprise etching the first bank material layer not covered with the photoresist; and etching a side surface of the first bank material layer to expose a lower surface of the second bank material layer.

The method may further comprise removing the second bank material layer and the first bank material layer in some areas such that a side surface of the second bank material layer and the side surface of the first bank material layer may be aligned.

The display device according to an embodiment may have a large light transmitting area, because a bank structure has an asymmetric cross section at a boundary of a non-display area surrounded by a display area.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a schematic perspective view of an electronic device according to an embodiment;

FIG. 2 is a perspective view illustrating a display device included in the electronic device according to an embodiment;

FIG. 3 is a cross-sectional view of the display device of FIG. 2 viewed from a side;

FIG. 4 is a plan view illustrating an arrangement of a light emitting area in a display area of a display device according to an embodiment;

FIG. 5 is a cross-sectional view illustrating an example of the display device taken along line I-I′ of FIG. 4;

FIG. 6 is an enlarged cross-sectional view of area A2 of FIG. 5;

FIG. 7 is an enlarged plan view of area A1 of FIG. 2;

FIG. 8 is a cross-sectional view illustrating an example of the display device taken along II-II′ of FIG. 7;

FIG. 9 is an enlarged cross-sectional view of area A3 of FIG. 8;

FIGS. 10 to 13 are enlarged cross-sectional views of area A3 of FIG. 8 illustrating another example of a display panel; and

FIGS. 14 to 20 are cross-sectional views sequentially illustrating a process of fabricating a display device according to an embodiment.

### DETAILED DESCRIPTION

The invention will now be described more fully hereinafter with reference to the accompanying drawings, in which example embodiments of the invention are illustrated. Aspects supported by the present disclosure may, however, be embodied in different forms and should not be construed as limited to the embodiments set forth herein. Rather, the example embodiments are provided such that this disclosure will be thorough and complete, and will fully convey the scope of example aspects of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” and the like may be used herein to describe various elements, these elements should not be limited by these terms. These terms are used to distinguish one element from another element. For instance, a first element discussed below may be termed a second element without departing from the teachings of the invention. Similarly, the second element may also be termed the first element. Terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

Hereinafter, embodiments will be described with reference to the accompanying drawings.

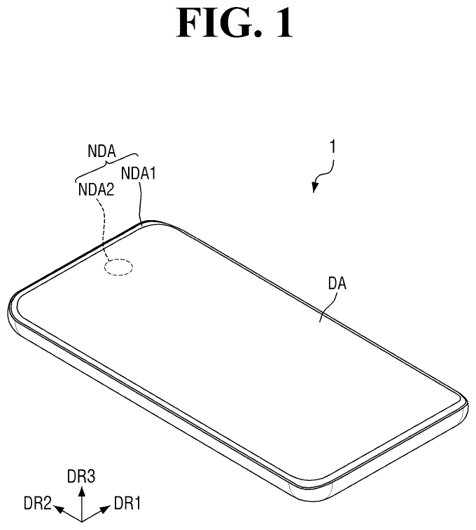

FIG. 1 is a schematic plan view of an electronic device 1 according to an embodiment.

Referring to FIG. 1, an electronic device 1 may display a moving image or a still image. The electronic device 1 may refer to any electronic device that provides a display screen. For example, the electronic device 1 may include televisions, laptop computers, monitors, billboards, Internet of things, mobile phones, smartphones, tablet personal computers (PCs), electronic watches, smart glasses, smartwatches, watch phones, head mounted displays, mobile communication terminals, electronic notebooks, electronic books, portable multimedia players (PMPs), navigation, game consoles, digital cameras, camcorders, and the like that provide the display screen.

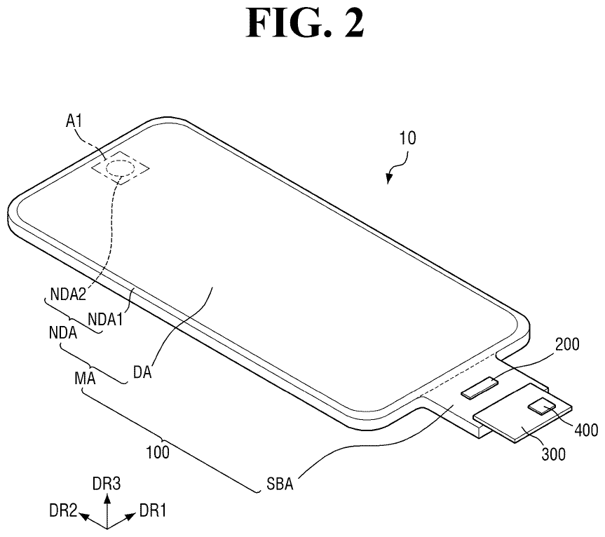

The electronic device 1 may include a display device (‘10’ in FIG. 2) that provides a display screen. Examples of the display device may include an inorganic light emitting diode display device, an organic light emitting display device, a quantum dot light emitting display device, a plasma display device, and a field emission display device. Hereinafter, it is illustrated that an organic light emitting diode display device is used as an example of the display device, but embodiments of the present disclosure are not limited thereto and may also be applied to other display devices as long as the same technical idea is applicable thereto.

Embodiments of the present disclosure support various shapes of the electronic device 1. For example, the electronic device 1 may have a shape such as, for example, a rectangle with a long width, a rectangle with a long length, a square, a quadrangle with rounded corners (vertices), other polygons, or a circle. A shape of a display area DA of the electronic device 1 may also be similar to an overall shape of the electronic device 1. In FIG. 1, the electronic device 1 having a rectangular shape with a long length in a second direction DR2 is illustrated.

The electronic device 1 may include a display area DA and a non-display area NDA. The display area DA is an area in which a screen may be displayed, and the non-display area NDA is an area in which a screen is not displayed. The display area DA may also be referred to as an active area, and the non-display area NDA may also be referred to as a non-active area. The display area DA may generally occupy the center of the electronic device 1.

The non-display area NDA may include a first non-display area NDA1 and a second non-display area NDA2. The first non-display area NDA1 may surround the display area DA, and the second non-display area NDA2 may be positioned inside the display area DA and surrounded by the display area DA. The second non-display area NDA2, which is an area where components for adding various functions to the electronic device 1 are disposed, may correspond to a component area.

FIG. 2 is a perspective view illustrating a display device 10 included in the electronic device according to an embodiment.

Referring to FIG. 2, the electronic device 1 according to an embodiment may include a display device 10. The display device 10 may provide a screen displayed by the electronic device 1. The display device 10 may have a planar shape similar to the shape of the electronic device 1. For example, the display device 10 may have a shape similar to a rectangle having short sides in a first direction DR1 and long sides in a second direction DR2. A corner where the short side in the first direction DR1 and the long side in the second direction DR2 meet may be rounded and have a curvature, but is not limited thereto, and the corner may be formed at a right angle. The planar shape of the display device 10 is not limited to the quadrangle, and may be formed similarly to other polygons, circles, or ovals.

The display device 10 may include a display panel 100, a display driver 200, a circuit board 300, a touch driver 400, and an optical device 500.

The display panel 100 may include a main area MA and a sub-area SBA.

The main area MA may include a display area DA including pixels that display an image, and a non-display area NDA where no image is displayed because of not including the pixels. The display area DA may emit light from a plurality of light emitting areas or a plurality of opening areas. For example, the display panel 100 may include a pixel circuit including switching elements, a pixel defining layer defining the light emitting areas or the opening areas, and a self-light emitting element.

For example, the self-light emitting element may include, but is not limited to, at least one of an organic light emitting diode (LED) including an organic light emitting layer, a quantum dot LED including a quantum dot light emitting layer, an inorganic LED including an inorganic semiconductor, and a micro LED.

The non-display area NDA may include a first non-display area NDA1 disposed around the display area DA, and a second non-display area NDA2 surrounded by the display area DA. The first non-display area NDA1 may be an area outside the display area DA and may be defined as an edge area of the main area MA of the display panel 100. The first non-display area NDA1 may include a gate driver (not illustrated) supplying gate signals to gate lines, and fan-out lines (not illustrated) connecting the display driver 200 and the display area DA. The second non-display area NDA2 may be positioned inside the display area DA and may be a light transmitting area through which light may pass.

The sub-area SBA may be an area extending from one side of the main area MA. The sub-area SBA may include a flexible material that may be bent, folded, rolled, or the like. In an example in which the sub-area SBA is bent, the sub-area SBA may overlap the main area MA in a thickness direction (a third direction DR3). The sub-area SBA may include the display driver 200 and a pad portion connected to the circuit board 300. In another embodiment, the sub-area SBA may be omitted, and the display driver 200 and the pad portion may be disposed in the non-display area NDA.

The display driver 200 may output signals and voltages for driving the display panel 100. The display driver 200 may supply data voltages to data lines. The display driver 200 may supply a power voltage to a power line and may supply a gate control signal to a gate driver. The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-area SBA, and the display driver 200 may overlap the main area MA in the thickness direction by bending of the sub-area SBA. As another example, the display driver 200 may be mounted on the circuit board 300.

The circuit board 300 may be attached onto the pad portion of the display panel 100 using an anisotropic conductive film (ACF). Lead lines of the circuit board 300 may be electrically connected to the pad portion of the display panel 100. The circuit board 300 may be a flexible film such as, for example, a flexible printed circuit board, a printed circuit board, or a chip on film.

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit, and may sense an amount of change in capacitance between the plurality of touch electrodes. For example, the touch driving signal may be a pulse signal having a predetermined frequency. The touch driver 400 may calculate whether an input is made and input coordinates based on the amount of change in capacitance between the plurality of touch electrodes. The touch driver 400 may be formed as an integrated circuit (IC).

The display device 10 may further include an optical device 500. The optical device 500 may be disposed in the second non-display area NDA2 on a rear surface of the display device 10. The optical device 500 may emit or receive light in infrared, ultraviolet, and visible light bands. For example, the optical device 500 may be an optical sensor that detects light incident on the display device 10, such as, for example, a proximity sensor, an illuminance sensor, and a camera sensor or an image sensor.

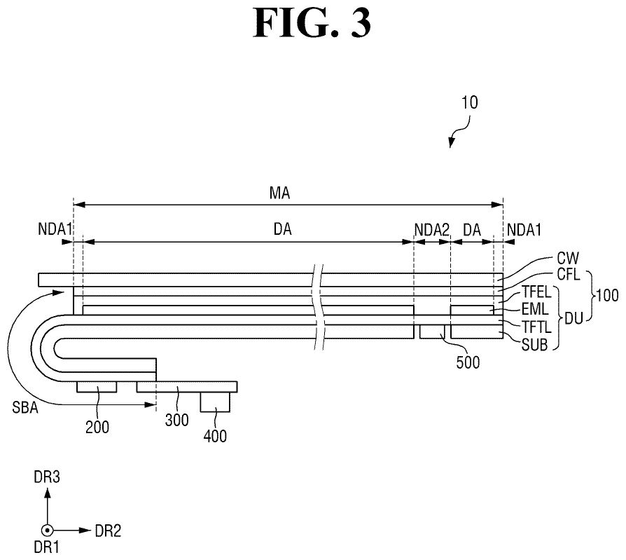

FIG. 3 is a cross-sectional view of the display device 10 of FIG. 2 viewed from a side. Specifically, FIG. 3 relates to a side surface of the display device 10 in FIG. 1 in a folded state.

Referring to FIG. 3, the display device 10 may include a display panel 100 and a cover window CW. The display panel 100 may include a substrate SUB, a thin film transistor layer TFTL, a light emitting element layer EML, a thin film encapsulation layer TFEL, and a color filter layer CFL.

The substrate SUB may be a base substrate or a base member. The substrate SUB may be a flexible substrate that may be bent, folded, rolled, or the like. For example, the substrate SUB may include a polymer resin such as, for example, polyimide PI, but is not limited thereto. In another embodiment, the substrate SUB may include a glass material or a metal material.

The thin film transistor layer TFTL may be disposed on the substrate SUB. The thin film transistor layer TFTL may include a plurality of thin film transistors constituting a pixel circuit of pixels. The thin film transistor layer TFTL may further include scan lines, data lines, power lines, scan control lines, fan-out lines connecting the display driver 200 and the data lines, and lead lines connecting the display driver 200 and the pad portion. Each of the thin film transistors may include a semiconductor area, a source electrode, a drain electrode, and a gate electrode. In an example in which the scan driver is formed on one side of the non-display area NDA of the display panel 100, the scan driver may include thin film transistors.

The thin film transistor layer TFTL may be disposed in the display area DA, the non-display area NDA, and the sub-area SBA. The thin film transistors, the scan lines, the data lines, and the power lines of each of the pixels of the thin film transistor layer TFTL may be disposed in the display area DA. The scan control lines and the fan-out lines of the thin film transistor layer TFTL may be disposed in the non-display area NDA. The lead lines of the thin film transistor layer TFTL may be disposed in the sub-area SBA.

The light emitting element layer EML may be disposed on the thin film transistor layer TFTL. The light emitting element layer EML may include a plurality of light emitting elements including a first electrode, a second electrode, and a light emitting layer to emit light, and a pixel defining layer defining pixels. The plurality of light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. In an example in which the first electrode receives a voltage through the thin film transistor of the thin film transistor layer TFTL and the second electrode receives a cathode voltage, holes and electrons may move to the organic light emitting layer through the hole transporting layer and the electron transporting layer, respectively, and may be bonded to each other in the organic light emitting layer to emit light.

In another embodiment, the light emitting element may include a quantum dot light emitting diode including a quantum dot light emitting layer, an inorganic light emitting diode including an inorganic semiconductor, or a micro light emitting diode.

The thin film encapsulation layer TFEL may cover an upper surface and side surfaces of the light emitting element layer EML, and may protect the light emitting element layer EML. The thin film encapsulation layer TFEL may include at least one inorganic film and at least one organic film for encapsulating the light emitting element layer EML.

The color filter layer CFL may be disposed on the thin film encapsulation layer TFEL. The color filter layer CFL may include a plurality of color filters corresponding to each of the plurality of light emitting areas. Each of the color filters may selectively transmit light of a specific wavelength and block or absorb light of a different wavelength. The color filter layer CFL may absorb a portion of light introduced from the outside of the display device 10 to reduce reflected light caused by external light. Therefore, the color filter layer CFL may prevent color distortion caused by reflection of external light.

As the color filter layer CFL is directly disposed on the thin film encapsulation layer TFEL, the display device 10 may be implemented without a separate substrate for the color filter layer CFL. Therefore, the display device 10 may have a relatively small thickness.

The cover window CW may be disposed on the color filter layer CFL. The cover window CW may be attached onto the color filter layer CFL by a transparent adhesive member such as, for example, an optically clear adhesive (OCA) film.

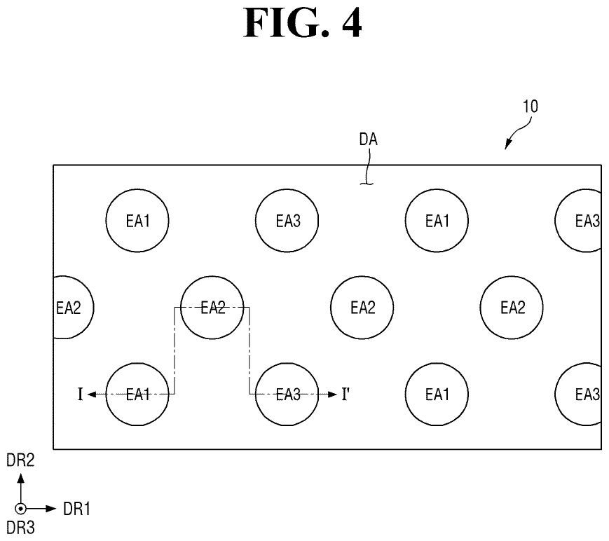

FIG. 4 is a plan view illustrating a portion of the display device 10 according to an embodiment. FIG. 4 is a plan view illustrating an arrangement of light emitting areas EA1, EA2, and EA3 in the display area DA of the display device 10.

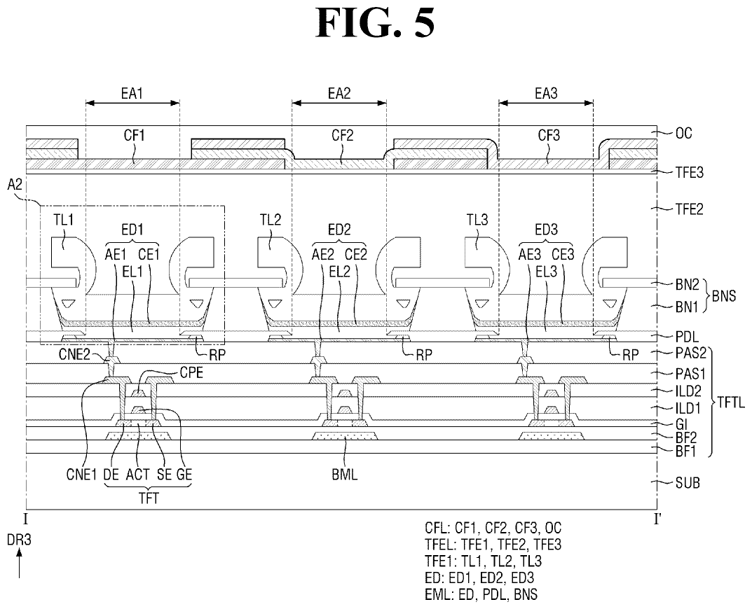

Referring to FIG. 4, the display device 10 may include a plurality of light emitting areas EA1, EA2, and EA3 disposed in the display area DA. The light emitting areas EA1, EA2, and EA3 may include a first light emitting area EA1, a second light emitting area EA2, and a third light emitting area EA3 that emit light of different colors. The first to third light emitting areas EA1, EA2, and EA3 may emit red, green, or blue light, respectively, and the color of light emitted from each of the light emitting areas EA1, EA2, and EA3 may be different depending on the types of light emitting elements (‘ED1’, ‘ED2’, and ‘ED3’ in FIG. 5) to be described later. As an example, the first light emitting area EA1 may emit red light, the second light emitting area EA2 may emit green light, and the third light emitting area EA3 may emit blue light. However, embodiments of the present disclosure are not limited thereto.

The plurality of light emitting areas EA1, EA2, and EA3 may be disposed in a pentile™ type, for example, a diamond pentile™ type. For example, the first light emitting area EA1 and the third light emitting area EA3 may be disposed spaced apart from each other in the first direction DR1, and may be alternately disposed in the first direction DR1 and the second direction DR2. The second light emitting area EA2 may be spaced apart from another adjacent second light emitting area EA2 in the first direction DR1 and the second direction DR2. The second light emitting area EA2 and the first light emitting area EA1, or the second light emitting area EA2 and the third light emitting area EA3, may be alternately arranged along any direction in a plane formed by the first direction DR1 and the second direction DR2.

The first to third light emitting areas EA1, EA2, and EA3 may be defined by a pixel defining layer (‘PDL’ in FIG. 5) to be described later.

FIG. 5 is a cross-sectional view illustrating a portion of the display device according to an embodiment. Specifically, FIG. 5 is a cross-sectional view of portion I-I′ of FIG. 4 and illustrates cross-sections of the substrate SUB, the thin film transistor layer TFTL, the light emitting element layer EML, the thin film encapsulation layer TFEL, and the color filter layer CFL.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic film capable of preventing permeation of air or moisture. For example, the first buffer layer BF1 may include a plurality of inorganic films alternately stacked.

The lower metal layer BML may be disposed on the first buffer layer BF1. For example, the lower metal layer BML may be formed of a single layer or a multi-layer formed of any one of molybdenum (Mo), aluminum (Al), chromium (Cr), gold (Au), titanium (Ti), nickel (Ni), neodymium (Nd), and copper (Cu), or an alloy thereof.

The second buffer layer BF2 may cover the first buffer layer BF1 and the lower metal layer BML. The second buffer layer BF2 may include an inorganic film capable of preventing permeation of air or moisture. For example, the second buffer layer BF2 may include a plurality of inorganic films alternately stacked.

The thin film transistor TFT may be disposed on the second buffer layer BF2, and may constitute a pixel circuit of each of the plurality of pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer BML and the gate electrode GE in the thickness direction DR3, and may be insulated from the gate electrode GE by the gate insulating layer GI. In a portion of the semiconductor layer ACT, a material of the semiconductor layer ACT may become a conductor to form the source electrode SE and the drain electrode DE.

The gate electrode GE may be disposed on the gate insulating layer GI. The gate electrode GE may overlap the semiconductor layer ACT in the thickness direction DR3, with the gate insulating layer GI interposed between the gate electrode GE and the semiconductor layer ACT.

The gate insulating layer GI may be disposed on the semiconductor layer ACT. For example, the gate insulating layer GI may cover the semiconductor layer ACT and the second buffer layer BF2, and may insulate the semiconductor layer ACT and the gate electrode GE from each other. The gate insulating layer GI may include a contact hole through which the first connection electrode CNE1 penetrates.

The first interlayer insulating layer ILD1 may cover the gate electrode GE and the gate insulating layer GI. The first interlayer insulating layer ILD1 may include a contact hole through which the first connection electrode CNE1 penetrates. The contact hole of the first interlayer insulating layer ILD1 may be connected to the contact hole of the gate insulating layer GI and a contact hole of the second interlayer insulating layer ILD2.

The capacitor electrode CPE may be disposed on the first interlayer insulating layer ILD1. The capacitor electrode CPE may overlap the gate electrode GE in the thickness direction DR3. The capacitor electrode CPE and the gate electrode GE may form a capacitance.

The second interlayer insulating layer ILD2 may cover the capacitor electrode CPE and the first interlayer insulating layer ILD1. The second interlayer insulating layer ILD2 may include a contact hole through which the first connection electrode CNE1 penetrates. The contact hole of the second interlayer insulating layer ILD2 may be connected to the contact hole of the first interlayer insulating layer ILD1 and the contact hole of the gate insulating layer GI.

The first connection electrode CNE1 may be disposed on the second interlayer insulating layer ILD2. The first connection electrode CNE1 may electrically connect the drain electrode DE of the thin film transistor TFT and the second connection electrode CNE2 to each other. The first connection electrode CNE1 may be inserted into the contact holes formed in the second interlayer insulating layer ILD2, the first interlayer insulating layer ILD1, and the gate insulating layer GI to be in contact with the drain electrode DE of the thin film transistor TFT.

The first passivation layer PAS1 may cover the first connection electrode CNE1 and the second interlayer insulating layer ILD2. The first passivation layer PAS1 may protect the thin film transistor TFT. The first passivation layer PAS1 may include a contact hole through which the second connection electrode CNE2 penetrates.

The second connection electrode CNE2 may be disposed on the first passivation layer PAS1. The second connection electrode CNE2 may electrically connect the first connection electrode CNE1 and pixel electrodes AE1, AE2, and AE3 of the light emitting element ED to each other. The second connection electrode CNE2 may be inserted into the contact hole formed in the first passivation layer PAS1 and be in contact with the first connection electrode CNE1.

The second passivation layer PAS2 may cover the second connection electrode CNE2 and the first passivation layer PAS1. The second passivation layer PAS2 may include contact holes through which the pixel electrodes AE1, AE2, and AE3 of the light emitting element ED penetrate.

The light emitting element layer EML may be disposed on the thin film transistor layer TFTL. The light emitting element layer EML may include a light emitting element ED, a pixel defining layer PDL, a capping layer CAP, and a bank structure BNS. The light emitting element ED may include pixel electrodes AE1, AE2, and AE3, light emitting layers EL1, EL2, and EL3, and common electrodes CE1, CE2, and CE3.

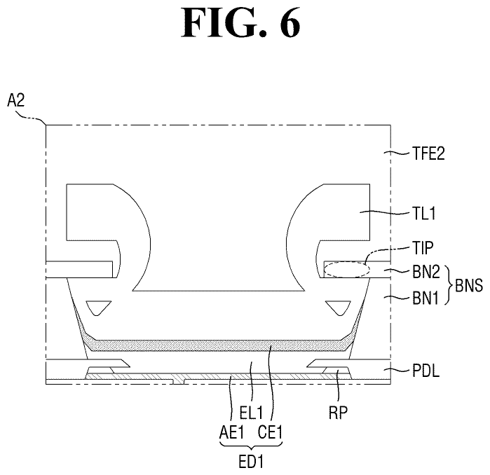

FIG. 6 is a cross-sectional view illustrating a first light emitting area EA1 of the display device 10 according to another embodiment. Specifically, FIG. 6 is an enlarged view illustrating area A2 of FIG. 5.

Referring to FIG. 6 in addition to FIG. 5, the display device 10 may include a plurality of light emitting areas EA1, EA2, and EA3 disposed in the display area DA. The light emitting areas EA1, EA2, and EA3 may be defined as areas where the pixel electrodes AE1, AE2, and AE3, the light emitting layers EL1, EL2, and EL3, and the common electrodes CE1, CE2, and CE3 overlap in the thickness direction of the substrate SUB. The light emitting areas EA1, EA2, and EA3 may include an area where light is emitted from the light emitting elements ED1, ED2, and ED3 in which the pixel electrodes AE1, AE2, and AE3, the light emitting layers EL1, EL2, and EL3, and the common electrodes CE1, CE2, and CE3 are sequentially stacked and passes through the color filter layer CFL in the third direction DR3. The light emitting areas EA1, EA2, and EA3 may include a first light emitting area EA1, a second light emitting area EA2, and a third light emitting area EA3 that are spaced apart from each other and emit light of the same or different colors.

In an embodiment, the areas or sizes of the first to third light emitting areas EA1, EA2, and EA3 may be the same or different from each other. For example, in the display device 10, the first light emitting area EA1, the second light emitting area EA2, and the third light emitting area EA3 may have different areas. However, embodiments of the present disclosure are not limited thereto. The area of the third light emitting area EA3 may be greater than the areas of the first light emitting area EA1 and the second light emitting area EA2, and the area of the second light emitting area EA2 may be greater than the area of the first light emitting area EA1. Intensities of light emitted from the light emitting areas EA1, EA2, and EA3 may vary depending on the areas of the light emitting areas EA1, EA2, and EA3, and a color of a screen displayed on the display device 10 may be controlled by adjusting the areas of the light emitting areas EA1, EA2, and EA3.

In the display device 10, one first light emitting area EA1, one second light emitting area EA2, and one third light emitting area EA3 disposed adjacent to each other may form one pixel group. One pixel group may express a white gradation by including the light emitting areas EA1, EA2, and EA3 emitting light of different colors. However, embodiments of the present disclosure are not limited thereto, and a combination of the light emitting areas EA1, EA2, and EA3 constituting one pixel group may be variously modified according to the arrangement of the light emitting areas EA1, EA2, and EA3, and the colors of the light emitted therefrom.

The display device 10 may include a plurality of light emitting elements ED1, ED2, and ED3 disposed in different light emitting areas EA1, EA2, and EA3. The light emitting elements ED1, ED2, and ED3 may include a first light emitting element ED1 disposed in the first light emitting area EA1, a second light emitting element ED2 disposed in the second light emitting area EA2, and a third light emitting element ED3 disposed in the third light emitting area EA3.

Each of the light emitting elements ED1, ED2, and ED3 includes pixel electrodes AE1, AE2, and AE3, light emitting layers EL1, EL2, and EL3, and common electrodes CE1, CE2, and CE3, and the light emitting elements ED1, ED2, and ED3 disposed in different light emitting areas EA1, EA2, and EA3 may emit light of different colors depending on the material of the light emitting layers EL1, EL2, and EL3. For example, the first light emitting element ED1 disposed in the first light emitting area EA1 may emit red light having a peak wavelength in the range of 610 nm to 650 nm, the second light emitting element ED2 disposed in the second light emitting area EA2 may emit green light having a peak wavelength in the range of 510 nm to 550 nm, and the third light emitting element ED3 disposed in the third light emitting area EA3 may emit blue light having a peak wavelength in the range of 440 nm to 480 nm. The first to third light emitting areas EA1, EA2, and EA3 constituting one pixel may express a white gradation by including the light emitting elements ED1, ED2, and ED3 that emit light of different colors. Alternatively, the light emitting layers EL1, EL2, and EL3 may include two or more materials that emit light of different colors, such that one light emitting layer may emit mixed light. For example, the light emitting layers EL1, EL2, and EL3 may emit yellow light by including a material that emits red light and a material that emits green light, or may emit white light by including a material that emits red light, a material that emits green light, and a material that emits blue light.

The pixel electrodes AE1, AE2, and AE3 may be disposed on the second passivation layer PAS2. The pixel electrodes AE1, AE2, and AE3 may be respectively disposed in the plurality of light emitting areas EA1, EA2, and EA3. The pixel electrodes AE1, AE2, and AE3 may include a first pixel electrode AE1 disposed in the first light emitting area EA1, a second pixel electrode AE2 disposed in the second light emitting area EA2, and a third pixel electrode AE3 disposed in the third light emitting area EA3. The first pixel electrode AE1, the second pixel electrode AE2, and the third pixel electrode AE3 may be disposed to be spaced apart from each other on the second passivation layer PAS2.

The pixel electrodes AE1, AE2, and AE3 may be electrically connected to the drain electrode DE of the thin film transistor TFT through the first and second connection electrodes CNE1 and CNE2. Edges of the pixel electrodes AE1, AE2, and AE3 spaced apart from each other may be covered by the pixel defining layer PDL, such that the first to third pixel electrodes AE1, AE2, and AE3 may be insulated from each other.

The pixel electrodes AE1, AE2, and AE3 may include a transparent electrode material and/or a conductive metal material, and may have a single-layer or multi-layer structure. The metal material may be one or more of silver (Ag), copper (Cu), aluminum (Al), nickel (Ni), lanthanum (La), titanium (Ti), and titanium nitride (TiN). The transparent electrode material may be one or more of Indium Tin Oxide (ITO), Indium Zinc Oxide (IZO), and Indium Tin Zinc Oxide (ITZO).

The light emitting layers EL1, EL2, and EL3 may be disposed on the pixel electrodes AE1, AE2, and AE3. The light emitting layers EL1, EL2, and EL3 may be organic light emitting layers formed of organic materials, and may be formed on the pixel electrodes AE1, AE2, and AE3 through a deposition process. The light emitting layers EL1, EL2, and EL3 may have a multi-layer structure, and a hole injection material, a hole transporting material, a light emitting material, an electron transporting material, or/and an electron injection material may each constitute a layer. In an example in which the thin film transistor TFT applies a predetermined voltage to the pixel electrodes AE1, AE2, and

AE3 of the light emitting elements ED1, ED2, and ED3, and the common electrodes CE1, CE2, and CE3 of the light emitting elements ED1, ED2, and ED3 receive a common voltage or a cathode voltage, holes and electrons are each injected and transported, and the holes and electrons may be bonded to each other in the light emitting layers EL1, EL2, and EL3 to emit light.

The light emitting layers EL1, EL2, and EL3 may include a first light emitting layer EL1, a second light emitting layer EL2, and a third light emitting layer EL3 disposed in different light emitting areas EA1, EA2, and EA3, respectively. The first light emitting layer EL1 may be disposed on the first pixel electrode AE1 in the first light emitting area EA1, the second light emitting layer EL2 may be disposed on the second pixel electrode AE2 in the second light emitting area EA2, and the third light emitting layer EL3 may be disposed on the third pixel electrode AE3 in the third light emitting area EA3. Each of the plurality of light emitting layers EL1, EL2, and EL3 may emit different colors, or one light emitting layer EL1, EL2, and EL3 may emit mixed light. In an embodiment, the first light emitting layer EL1 may emit red light, the second light emitting layer EL2 may emit green light, and the third light emitting layer EL3 may emit blue light.

The light emitting layers EL1, EL2, and EL3 may be disposed on an upper surface of the pixel defining layer PDL. In an embodiment, a side surface of a residual pattern RP may be depressed compared to a side surface of the pixel defining layer PDL, and a portion of the light emitting layers EL1, EL2, and EL3 may be disposed in a space between the pixel electrodes AE1, AE2, and AE3 and the pixel defining layer PDL. In an embodiment, the light emitting layers EL1, EL2, and EL3 may be in contact with the pixel defining layer PDL, the residual pattern RP, and the pixel electrodes AE1, AE2, and AE3.

The common electrodes CE1, CE2, and CE3 may be disposed on the light emitting layers EL1, EL2, and EL3. The common electrodes CE1, CE2, and CE3 include a transparent conductive material such that the light generated in the light emitting layers EL1, EL2, and EL3 may be emitted. The common electrodes CE1, CE2, and CE3 may receive a common voltage or a low potential voltage. In an example in which the pixel electrodes AE1, AE2, and AE3 receive a voltage corresponding to the data voltage and the common electrodes CE1, CE2, and CE3 receive a low potential voltage, the light emitting layers EL1, EL2, and EL3 may emit light as a potential difference is formed between the pixel electrodes AE1, AE2, and AE3 and the common electrodes CE1, CE2, and CE3.

The common electrodes CE1, CE2, and CE3 may include a first common electrode CE1, a second common electrode CE2, and a third common electrode CE3 disposed in different light emitting areas EA1, EA2, and EA3. The first common electrode CE1 may be disposed on the first light emitting layer EL1 in the first light emitting area EA1, the second common electrode CE2 may be disposed on the second light emitting layer EL2 in the second light emitting area EA2, and the third common electrode CE3 may be disposed on the third light emitting layer EL3 in the third light emitting area EA3. The first to third common electrodes CE1, CE2, and CE3 may be spaced apart from each other.

A capping layer (not illustrated) may be optionally disposed on the common electrodes CE1, CE2, and CE3. The capping layer may include an organic or inorganic insulating material and cover the patterns disposed on the light emitting elements ED1, ED2, and ED3. The capping layer may prevent the light emitting elements ED1, ED2, and ED3 from being damaged by external air. The capping layer may include a first capping layer, a second capping layer, and a third capping layer respectively disposed in different light emitting areas EA1, EA2, and EA3. The first to third capping layers may be spaced apart from each other.

The pixel defining layer PDL may be disposed on the second passivation layer PAS2 and expose the upper surfaces of the pixel electrodes AE1, AE2, and AE3 to define the light emitting areas EA1, EA2, and EA3. The pixel defining layer PDL may include an inorganic insulating material. The pixel defining layer PDL may include at least one of a silicon nitride layer, a silicon oxynitride layer, a silicon oxide layer, a titanium oxide layer, an aluminum oxide layer, a tantalum oxide layer, a hafnium oxide layer, a zinc oxide layer, and an amorphous silicon layer, but is not limited thereto.

According to an embodiment, the pixel defining layer PDL may be disposed on the edges of the pixel electrodes AE1, AE2, and AE3 and may be spaced apart from the upper surfaces of the pixel electrodes AE1, AE2, and AE3. The pixel defining layer PDL may partially overlap the upper surfaces of the pixel electrodes AE1, AE2, and AE3 in the thickness direction DR3 of the substrate SUB and may not be in direct contact with the upper surfaces of the pixel electrodes AE1, AE2, and AE3, and the residual pattern RP may be disposed between the pixel defining layer PDL and the pixel electrodes AE1, AE2, and AE3. The pixel defining layer PDL may be in direct contact with the side surfaces of the pixel electrodes AE1, AE2, and AE3.

The residual pattern RP may be disposed on the edge of each of the pixel electrodes AE1, AE2, and AE3. The pixel defining layer PDL may not be in direct contact with the upper surfaces of the pixel electrodes AE1, AE2, and AE3 due to the residual pattern RP. The residual pattern RP may be formed by removing a portion of a sacrificial layer disposed on the pixel electrodes AE1, AE2, and AE3 during the process of fabricating the display device 10. The residual pattern RP may include a metal or oxide semiconductor material.

The display device 10 may include a plurality of bank structures BNS disposed on the pixel defining layer PDL. The bank structure BNS may have a structure in which banks BN1 and BN2 including different materials are sequentially stacked, may include a plurality of openings including the light emitting areas EA1, EA2, and EA3, and may be disposed to overlap light blocking areas of the color filters CF1, CF2, and CF3, which will be described later.

A first bank BN1 may be disposed on the pixel defining layer PDL. A side surface of the first bank BN1 may be more depressed than a side surface of the pixel defining layer PDL in a direction opposite to the direction toward the light emitting areas EA1, EA2, and EA3. The side surface of the first bank BN1 may be more depressed than a side surface of a second bank BN2, which will be described later, in the direction opposite to the direction toward the light emitting areas EA1, EA2, and EA3. That is, for example, a side surface of the first bank BN1 may be more recessed away from a given light emitting area (e.g., light emitting area EA1) compared to a respective side surface of the pixel defining layer PDL.

According to an embodiment, the first bank BN1 may include a metal material. In an embodiment, the first bank BN1 may include aluminum (Al), an oxide of aluminum (Al), or an alloy of aluminum (Al).

The common electrodes CE1, CE2, and CE3 may be in direct contact with the side surfaces of the first bank BN1. For example, with respect to each of the common electrodes CE1, CE2, and CE3, one end and the other end may respectively be in contact with side surfaces of the first bank BN1. The common electrodes CE1, CE2, and CE3 of different light emitting elements ED1, ED2, and ED3 may each be in direct contact with the first bank BN1, and the first bank BN1 includes a conductive material, such that the common electrodes CE1, CE2, and CE3 may be electrically connected to each other through the first bank BN1. The first bank BN1 may have an upper surface positioned higher than the common electrodes CE1, CE2, and CE3. A height from the substrate SUB to the upper surface of the first bank BN1 may be greater than a height from the substrate SUB to the common electrodes CE1, CE2, and CE3.

According to an embodiment, the light emitting layers EL1, EL2, and EL3 may be in direct contact with the side surface of the first bank BN1. A contact area between the common electrodes CE1, CE2, and CE3 and the side surface of the first bank BN1 may be greater than a contact area between the light emitting layers EL1, EL2, EL3 and the side surface of the first bank BN1. The common electrodes CE1, CE2, and CE3 may be disposed to have a greater area than the light emitting layers EL1, EL2, and EL3 on the side surface of the first bank BN1, or at a higher position on the side surface of the first bank BN1. Expressed another way, surface areas of the common electrodes CE1, CE2, and CE3 in contact with side surfaces of the first bank BN1 may be greater than (or positioned higher than) surface areas of the light emitting layers EL1, EL2, and EL3 in contact with the side surfaces of the first bank BN1. Since the common electrodes CE1, CE2, and CE3 of the different light emitting elements ED1, ED2, and ED3 are electrically connected through the first bank BN1, the contact between the common electrodes CE1, CE2, and CE3 with the first bank BN1 over a greater area may provide advantages compared to other approaches.

A second bank BN2 may be disposed on the first bank BN1. The second bank BN2 may include an opening that overlaps each of the light emitting areas EA1, EA2, and EA3, and each opening may include a side surface. The second bank BN2 may include a tip or eaves, which is a protruding area, compared to the first bank BN1. The side surface of the second bank BN2 may protrude further toward the light emitting areas EA1, EA2, and EA3 compared to the side surface of the first bank BN1.

As the side surface of the second bank BN2 has a shape that protrudes further toward the light emitting areas EA1, EA2, and EA3 compared to the side surface of the first bank BN1, an undercut structure of the first bank BN1 may be formed below the tip of the second bank BN2.

In the display device 10 according to an embodiment, as the bank structure BNS includes the tip protruding toward the light emitting areas EA1, EA2, and EA3, the light emitting layers EL1, EL2, and EL3 and the common electrodes CE1, CE2, and CE3 that are spaced apart from each other may be formed through the deposition and etching process rather than the mask process. In some aspects, embodiments of the present disclosure support individually forming different layers in different light-emitting areas EA1, EA2, and EA3 through the deposition process. For example, embodiments of the present disclosure support forming the light emitting layers EL1, EL2, and EL3 of the light emitting elements ED1, ED2, and ED3 and the common electrodes CE1, CE2, and CE3 through a deposition process without using a mask, such that the deposited materials are not connected between the light emitting areas EA1, EA2, and EA3 and are disconnected from the bank structure BNS interposed between the deposited materials by the tip of the second bank BN2. Embodiments of the present disclosure support individually forming different layers in different light emitting areas EA1, EA2, and EA3 through a process of forming a material for forming a specific layer on the entire surface of the display device 10 and then etching and removing a layer formed in an unwanted area. In the display device 10, embodiments of the present disclosure support forming different light emitting elements ED1, ED2, and ED3 for each of the light emitting areas EA1, EA2, and EA3 through the deposition and etching process without using the mask process, omitting an unnecessary configuration from the display device 10, and minimizing the area of the non-display area NDA.

The second bank BN2 may include a metal material different from the metal material of the first bank BN1. The metal material of the second bank BN2 is removed by dry etching along with the metal material of the first bank BN1. The metal material of the second bank BN2 may be a material that has a much slower etching rate than the etching rate of the first bank BN1 or is not etched, when performing wet etching. In an embodiment, the first bank BN1 may include aluminum (Al), an oxide of aluminum (Al), or an alloy of aluminum (Al), and the second bank BN2 may include titanium (Ti), an oxide of titanium (Ti), or an alloy of titanium (Ti).

The tip of the second bank BN2 may overlap the common electrodes CE1, CE2, and CE3, the light emitting layers EL1, EL2, and EL3, and/or the pixel defining layer PDL in the direction DR3 perpendicular to the substrate SUB. One end and the other end of the common electrodes CE1, CE2, and CE3 may overlap the second bank BN2 in the thickness direction DR3 of the substrate SUB.

The thin film encapsulation layer TFEL may be disposed on the light emitting elements ED1, ED2, and ED3 and the bank structure BNS, and may cover the plurality of light emitting elements ED1, ED2, and ED3 and the bank structure BNS. The thin film encapsulation layer TFEL may include at least one inorganic film to prevent oxygen or moisture from permeating into the light emitting element layer EML. The thin film encapsulation layer TFEL may include at least one organic film to protect the light emitting element layer EML from foreign substances such as, for example, dust.

In an embodiment, the thin film encapsulation layer TFEL may include a lower inorganic encapsulation layer TFE1, an organic encapsulation layer TFE2, and an upper inorganic encapsulation layer TFE3 that are sequentially stacked.

Each of the lower inorganic encapsulation layer TFE1 and the upper inorganic encapsulation layer TFE3 may include one or more inorganic insulating materials. The inorganic insulating material may be any one of silicon oxide, silicon nitride, and silicon oxynitride, for example, aluminum oxide, titanium oxide, tantalum oxide, hafnium oxide, zinc oxide, silicon oxide, silicon nitride, and/or silicon oxynitride.

The organic encapsulation layer TFE2 may include a polymer-based material. Examples of the polymer-based material may include an acrylic resin, an epoxy-based resin, polyimide, polyethylene, and the like. For example, the organic encapsulation layer TFE2 may include an acrylic resin, for example, polymethyl methacrylate or polyacrylic acid. The organic encapsulation layer TFE2 may be formed by curing a monomer or applying a polymer.

The lower inorganic encapsulation layer TFE1 may be disposed on the light emitting elements ED1, ED2, and ED3 and the bank structure BNS. The lower inorganic encapsulation layer TFE1 may include a first inorganic layer TL1, a second inorganic layer TL2, and a third inorganic layer TL3 disposed to respectively correspond to the different light emitting areas EA1, EA2, and EA3. The lower inorganic encapsulation layer TFE1 may optionally further include a fourth inorganic layer TL4 disposed in the second non-display area NDA2 and the light transmitting area TA. The first inorganic layer TL1, the second inorganic layer TL2, and the third inorganic layer TL3 may each include an inorganic insulating material covering the light emitting elements ED1, ED2, and ED3. The first inorganic layer TL1, the second inorganic layer TL2, and the third inorganic layer TL3 may prevent the light emitting elements ED1, ED2, and ED3 from being damaged by external air.

Since the lower inorganic encapsulation layer TFE1 may be formed through chemical vapor deposition (CVD), the lower inorganic encapsulation layer TFE1 may be formed along a step (stepped portion) of the deposited layer. For example, the first inorganic layer TL1, the second inorganic layer TL2, and the third inorganic layer TL3 may form a thin film even on the lower portion of the undercut formed by the tip of the bank structure BNS. The lower inorganic encapsulation layers TL1, TL2, and TL3 may be disposed along the upper, side, and lower surfaces of the second bank BN2, the side surface of the first bank BN1, and the upper surfaces of the common electrodes CE1, CE2, and CE3. The lower inorganic encapsulation layers TL1, TL2, and TL3 may be in contact with the lower surface of the second bank BN2, thereby preventing moisture permeation from external air.

The first inorganic layer TL1 may be disposed on the first light emitting element ED1 and the bank structure BNS around the first light emitting element ED1, without overlapping the second light emitting element ED2 and the third light emitting element ED3. The second inorganic layer TL2 may be disposed on the second light emitting element ED2 and the bank structure BNS around the second light emitting element ED2, without overlapping the first light emitting element ED1 and the third light emitting element ED3. The third inorganic layer TL3 may be disposed on the third light emitting element ED3 and the bank structure BNS around the third light emitting element ED3, without overlapping the first light emitting element ED1 and the second light emitting element ED2. The fourth inorganic layer TLA may overlap the second non-display area NDA2 and the light transmitting area TA, without overlapping the first to third light emitting elements ED1, ED2, and ED3.

The first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. The first inorganic layer TL1, the second inorganic layer TL2, and the third inorganic layer TL3 may be disposed to be spaced apart from each other on the bank structure BNS.

The lower inorganic encapsulation layers TL1, TL2, and TL3 are disposed on the upper and lower surfaces of the light emitting elements ED1, ED2, and ED3 and the second bank BN2 therearound, but may be spaced apart from the upper surface of the second bank BN2. That is, the lower inorganic encapsulation layers TL1, TL2, and TL3 may have an undercut structure on the second bank BN2. A separation space between the lower inorganic encapsulation layers TL1, TL2, and TL3 and the upper surface of the second bank BN2 may be a space where the materials of the light emitting layers EL1, EL2, and EL3 and the common electrodes CE1, CE2, and CE3 deposited on the entire surface are removed.

The organic encapsulation layer TFE2 is disposed on the second bank BN2 and the lower inorganic encapsulation layers TL1, TL2, and TL3. A portion of the organic encapsulation layer TFE2 may be disposed in the separation space between the lower inorganic encapsulation layers TL1, TL2, and TL3 and the upper surface of the second bank BN2. In the area where the second bank BN2 and the lower inorganic encapsulation layers TL1, TL2, and TL3 overlap, the second bank BN2, the organic encapsulation layer TFE2, and the lower inorganic encapsulation layers TL1, TL2, and TL3 may be sequentially disposed. In the tip area, the organic encapsulation layer TFE2 and the lower inorganic encapsulation layers TL1, TL2, and TL3 may be sequentially disposed on the second bank BN2, and the organic encapsulation layer TFE2 may be disposed again on the lower inorganic encapsulation layers TL1, TL2, and TL3. In other words, a portion of the organic encapsulation layer TFE2 may be disposed between the upper surface of the second bank BN2 and the lower inorganic encapsulation layers TL1, TL2, and TL3 on the tip of the second bank BN2, and another portion of the organic encapsulation layer TFE2 may be disposed on the lower inorganic encapsulation layers TL1, TL2, and TL3.

In an embodiment, in the display area DA, the entirety of the upper surface of the second bank BN2 may be in contact with the organic encapsulation layer TFE2. A first lower surface of the lower inorganic encapsulation layers TL1, TL2, and TL3 (i.e., respective first lower surfaces of the lower inorganic encapsulation layers TL1, TL2, and TL3) may be a surface opposite to the upper surface of the second bank BN2 and may be in contact with the organic encapsulation layer TFE2. The organic encapsulation layer TFE2 may be in contact with the side surface of the second bank BN2.

The upper inorganic encapsulation layer TFE3 may be disposed on the organic encapsulation layer TFE2. The upper inorganic encapsulation layer TFE3 may include aluminum oxide, titanium oxide, tantalum oxide, hafnium oxide, zinc oxide, silicon oxide, silicon nitride, and/or silicon oxynitride.

The display device 10 may include a plurality of color filters CF1, CF2, and CF3 disposed on the light emitting areas EA1, EA2, and EA3. Each of the plurality of color filters CF1, CF2, and CF3 may include a filtering pattern area and a light blocking area. The filtering pattern area may be formed such that the filtering pattern area overlaps the light emitting areas EA1, EA2, and EA3 or the openings of the bank structures BNS, and the filtering pattern area may form a light outputting area from which light emitted from the light emitting areas EA1, EA2, and EA3 is emitted. The light blocking area is an area where light may not transmit through because the plurality of color filters CF1, CF2, and CF3 are stacked thereon.

The color filters CF1, CF2, and CF3 may include a first color filter CF1, a second color filter CF2, and a third color filter CF3 disposed to respectively correspond to different light emitting areas EA1, EA2, and EA3. The color filters CF1, CF2, and CF3 may include a colorant such as, for example, a dye or pigment that absorbs light in a wavelength band other than light in a specific wavelength band, and may be disposed to correspond to the colors of light emitted from the light emitting areas EA1, EA2, and EA3. For example, the first color filter CF1 may be a red color filter that is disposed such that the first color filter CF1 overlaps the first light emitting area EA1 and may transmit only first light of a red color. The second color filter CF2 may be a green color filter that is disposed such that the second color filter CF2 overlaps the second light emitting area EA2 and may transmit only second light of a green color. The third color filter CF3 may be a blue color filter that is disposed such that the third color filter CF3 overlaps the third light emitting area EA3 and may transmit only third light of a blue color.

In the display device 10, as the color filters CF1, CF2, and CF3 are disposed to overlap each other, intensity of reflected light caused by external light may be reduced. Furthermore, the color of light reflected by external light may also be controlled by adjusting the arrangement, shape, and area of the color filters CF1, CF2, and CF3 in a plan view.

An overcoat layer OC may be disposed on the color filters CF1, CF2, and CF3 to planarize upper ends of the color filters CF1, CF2, and CF3. The overcoat layer OC may be a colorless light-transmitting layer having no color in a visible light band. For example, the overcoat layer OC may include a colorless light-transmitting organic material such as, for example, an acryl-based resin.

In an embodiment, the display panel 100 may include a second non-display area NDA2 inside the display area DA, which is a light transmitting area TA through which light transmits.

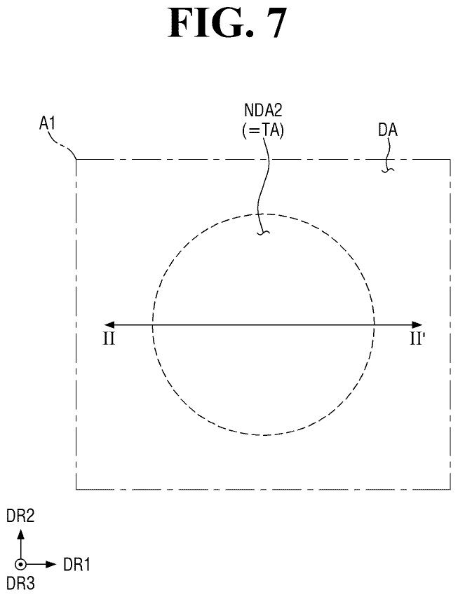

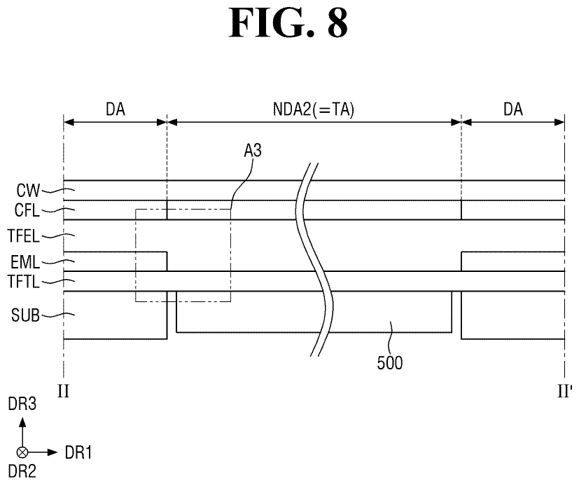

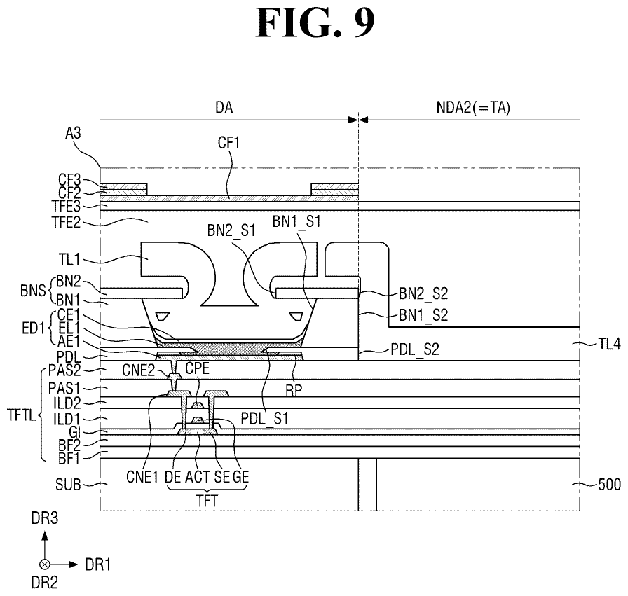

FIG. 7 is an enlarged view of the second non-display area NDA2 of the display panel 100. FIG. 7 is an enlarged plan view of area A1 of FIG. 2 and FIG. 8 is a cross-sectional view illustrating an example of the display device taken along II-II′ of FIG. 7. FIG. 9 is an enlarged cross-sectional view of area A3 of FIG. 8.

Referring to FIGS. 7 to 9, the display panel 100 includes a display area DA in which the light emitting element layer EML is disposed and a second non-display area NDA2 in which the light emitting element layer EML is not disposed. The second non-display area NDA2 is a light transmitting area TA through which light transmits, and a configuration through which light may not transmit may be removed from the second non-display area NDA2. In an embodiment, the cover window CW, the thin film encapsulation layer TFEL, and the thin film transistor layer TFTL may overlap the second non-display area NDA2 and the light transmitting area TA. The thin film transistor layer TFTL may be exposed in the light transmitting area TA without being covered by the light emitting element layer EML.

The optical device 500 may be disposed in the second non-display area NDA2 and the light transmitting area TA. Light incident from the outside may pass through some layers in the light transmitting area TA and reach the optical device 500. It is illustrated in the drawings that the second non-display area NDA2 of the substrate SUB is removed and the optical device 500 is disposed at that position, but embodiments of the present disclosure are not limited thereto. The optical device 500 may be disposed on the rear surface of the substrate SUB without removing a portion of the substrate SUB.

At a boundary between the second non-display area NDA2 and the display area DA, the bank structure BNS may be disposed between the light emitting areas EA1, EA2, and EA3 and the second non-display area NDA2 and may have an asymmetric cross-section. The second bank BN2 includes a tip that protrudes toward the light emitting areas EA1, EA2, and EA3, but does not have an area protruding toward the second non-display area NDA2.

The first bank BN1 may include a first side surface BN1_S1 facing the light emitting areas EA1, EA2, and EA3, and a second side surface BN1_S2 facing the second non-display area NDA2. The second bank BN2 may include a first side surface BN2_S1 facing the light emitting areas EA1, EA2, and EA3, and a second side surface BN2_S2 facing the second non-display area NDA2. The first side surface BN1_S1 and the second side surface BN1_S2 of the first bank BN1 may be surfaces opposite to each other on a cross section of the substrate SUB cut in the thickness direction DR3. The first side surface BN2_S1 and the second side surface BN2_S2 of the second bank BN2 may be surfaces opposite to each other on a cross section of the substrate SUB cut in the thickness direction DR3. The first side surface BN2_S1 of the second bank BN2 may protrude further toward the light emitting areas EA1, EA2, and EA3 compared to the first side surface BN1_S1 of the first bank BN1, and the second side surface BN2_S2 of the second bank BN2 may be aligned with the second side surface BN1_S2 of the first bank BN1. Since the bank structure BNS through which light does not pass does not have the tip toward the light transmitting area TA, the display device 10 may have a wide light transmitting area TA.

The pixel defining layer PDL may have an asymmetric cross-section at the boundary between the second non-display area NDA2 and the display area DA. The pixel defining layer PDL may include a first side surface PDL_S1 facing the light emitting areas EA1, EA2, and EA3, and a second side surface PDL_S2 facing the second non-display area NDA2. The first side surface PDL_S1 and the second side surface PDL_S2 of the pixel defining layer PDL may be surfaces opposite to each other on a cross section of the substrate SUB cut in the thickness direction DR3. The pixel defining layer PDL may have the first side surface PDL_S1 that compared to the first bank BN1 protrudes further toward the light emitting areas EA1, EA2, and EA3, and may have the second side surface PDL_S2 aligned with the first bank BN1 toward the second non-display area NDA2 (the light transmitting area TA). The first side surface PDL_S1 of the pixel defining layer PDL, the first side surface BN1_S1 of the first bank BN1, and the first side surface BN2_S1 of the second bank BN2 are not aligned with each other, but the second side surface PDL_S2 of the pixel defining layer PDL, the second side surface BN1_S2 of the first bank BN1, and the second side surface BN2_S2 of the second bank BN2 may be aligned with each other.

As illustrated at least at FIG. 9, the first side surface BN2_S1 of the second bank BN2 faces a light emitting area (e.g., light emitting area EA1, light emitting area EA2, or light emitting area EA3). The second side surface BN2_S2 of the second bank BN2 faces the second non-display area NDA2 (the light transmitting area TA). Expressed another way, the first side surface BN2_S1 of the second bank BN2 protrudes over or is included in a light emitting area (e.g., light emitting area EA1, light emitting area EA2, or light emitting area EA3), and the second side surface BN2_S2 of the second bank BN2 protrudes into or is included in the second non-display area NDA2 (the light transmitting area TA).

The fourth inorganic layer TL4 may be disposed between the organic encapsulation layer TFE2 and the thin film transistor layer TFTL in the second non-display area NDA2 and the light transmitting area TA. The fourth inorganic layer TL4 may cover outer surfaces of the bank structure BNS, the pixel defining layer PDL, and the thin film transistor layer TFTL. The fourth inorganic layer TL4 may be disposed on the second side surface BN2_S2 of the second bank BN2, the second side surface BN1_S2 of the first bank BN1, and the second side surface PDL_S2 of the pixel defining layer PDL. A portion of the fourth inorganic layer TL4 may be disposed on the second bank BN2 and spaced apart from the upper surface of the second bank BN2. The organic encapsulation layer TFE2 may be disposed in a separation space between the fourth inorganic layer TL4 and the upper surface of the second bank BN2. In an embodiment, the fourth inorganic layer TL4 may be formed directly on the thin film transistor layer TFTL and may be in contact with the second passivation layer PAS2 of the thin film transistor layer TFTL.

The fourth inorganic layer TL4 may be formed during a process of forming any one of the first to third inorganic layers TL1, TL2, and TL3 of the lower inorganic encapsulation layer TFE1, and may include the same material or film quality as the one inorganic layer. The fourth inorganic layer TL4 may be spaced apart from the first to third inorganic layers TL1, TL2, and TL3, but is not limited thereto. The fourth inorganic layer TL4 may also be connected to any one of the first to third inorganic layers TL1, TL2, and TL3.

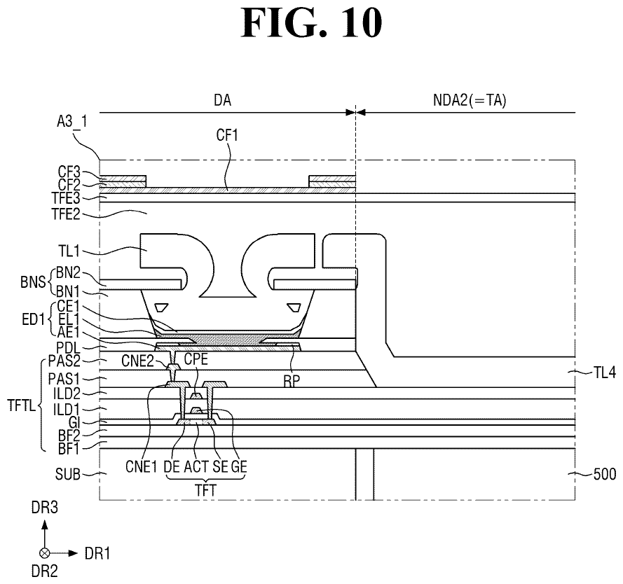

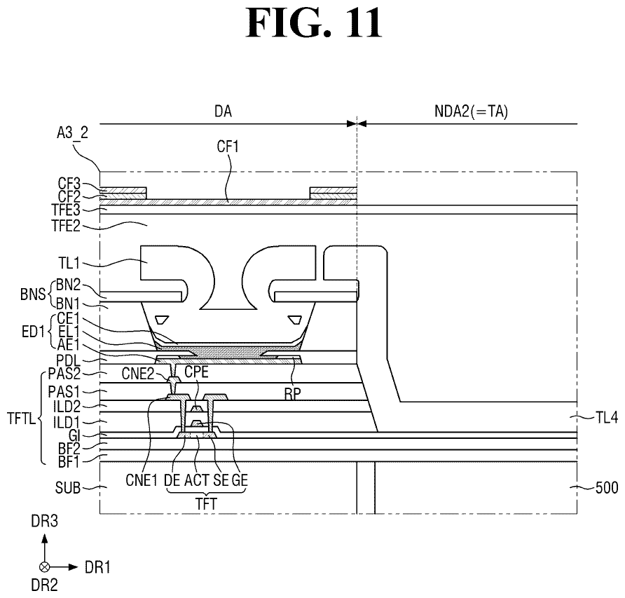

FIGS. 10 and 11 are enlarged cross-sectional views of area A3 of FIG. 8 illustrating another example of a display panel. To increase light transmittance in the second non-display area NDA2 and the light transmitting area TA, a portion of the thin film transistor layer TFTL may be removed. After a portion of the thin film transistor layer TFTL is removed through a laser process, a thin film encapsulation layer TFEL may be formed.

An embodiment of FIG. 10 is different from the embodiment of FIG. 9 in that in the second non-display area NDA2 and the light transmitting area TA, the second passivation layer PAS2 and the first passivation layer PAS1 of the thin film transistor layer TFTL are removed and the second interlayer insulating layer ILD2 is exposed.

Referring to FIG. 10, the optical device 500, the first buffer layer BF1, the second buffer layer BF2, the gate insulating layer GI, the first interlayer insulating layer ILD1, and the second interlayer insulating layer ILD2 may be disposed in the non-display area NDA2 and the light transmitting area TA. Portions of the second passivation layer PAS2 and the first passivation layer PAS1 may remain at the edges of the non-display area NDA2 and the light transmitting area TA. The fourth inorganic layer TL4 may be in contact with the second passivation layer PAS2, the first passivation layer PAS1, and the second interlayer insulating layer ILD2.

The embodiment of FIG. 11 is different from the embodiment of FIG. 9 in that in the second non-display area NDA2 and the light transmitting area TA, the second passivation layer PAS2, the first passivation layer PAS1, the second interlayer insulating layer ILD2, and the first interlayer insulating layer ILD1 of the thin film transistor layer TFTL are removed and the gate insulating layer GI is exposed.

Referring to FIG. 11, the optical device 500, the first buffer layer BF1, the second buffer layer BF2, and the gate insulating layer GI may be disposed in the non-display area NDA2 and the light transmitting area TA. Portions of the second passivation layer PAS2, the first passivation layer PAS1, the second interlayer insulating layer ILD2, and the first interlayer insulating layer ILD1 may remain at the edges of the non-display area NDA2 and the light transmitting area TA. The fourth inorganic layer TL4 may be in contact with the second passivation layer PAS2, the first passivation layer PAS1, the second interlayer insulating layer ILD2, the first interlayer insulating layer ILD1, and the gate insulating layer GI.

The present disclosure is not limited to the example aspects illustrated in FIGS. 10 and 11, and some layers of the thin film transistor layer TFTL may be removed from the second non-display area NDA2 and the light transmitting area TA to increase light transmittance.

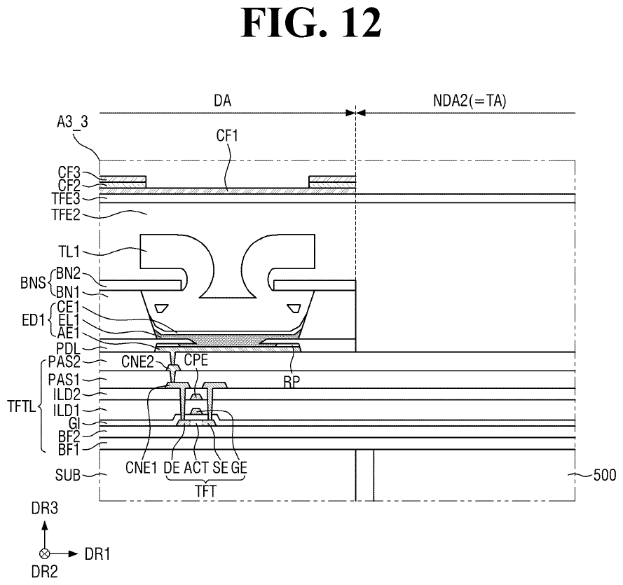

FIG. 12 is an enlarged cross-sectional view of area A3 of FIG. 8 illustrating another example of a display panel. An embodiment of FIG. 12 is different from the embodiment of FIG. 8 in that the fourth inorganic layer TL4 is omitted. The organic encapsulation layer TFE2 may be directly disposed on the thin film transistor layer TFTL.

When the fourth inorganic layer TL4 includes a plurality of inorganic films having different refractive indices, the transmittance of light passing through the second interlayer insulating film 142 may be lowered due to differences in the refractive indices of the plurality of inorganic films. Alternatively, when the fourth inorganic layer TL4 is a single film different from the second passivation layer PAS2, the transmittance of light passing through the fourth inorganic layer TL4 may be lowered due to a difference in refractive indices of the fourth inorganic layer TL4 and the second passivation layer PAS2.

As illustrated in FIG. 12, based on the formation of the organic encapsulation layer TFE2 directly on the thin film transistor layer TFTL in the second non-display area NDA2 and the light transmitting area TA, embodiments of the present disclosure may prevent the transmittance of light passing through the light transmitting area TA from being reduced due to the fourth inorganic layer TL4.

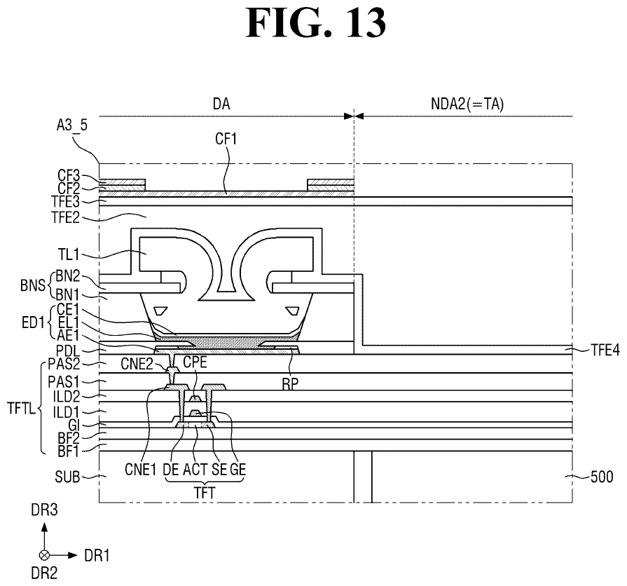

FIG. 13 is an enlarged cross-sectional view of area A3 of FIG. 8 illustrating another example of a display panel. The embodiment of FIG. 13 is different from the embodiment of FIG. 12 in that a reinforcement layer TFE4 is further included between the organic encapsulation layer TFE2 and the thin film transistor layer TFTL, between the organic encapsulation layer TFE2 and the lower inorganic encapsulation layer TL1, and between the organic encapsulation layer TFE2 and the second bank BN2.

The reinforcement layer TFE4 may be formed on the entire surface of the substrate SUB and may be disposed between the lower inorganic encapsulation layer TFE1 (e.g., lower inorganic encapsulation layers TL1, TL2, and TL3 of the lower inorganic encapsulation layer TFE1) and the organic encapsulation layer TFE2. The reinforcement layer TFE4 may prevent the lower inorganic encapsulation layer TFE1 from being deformed or separated from the lower surface of the tip of the second bank BN2 during an etching or cleaning process. The reinforcement layer TFE4 may be a portion of the thin film encapsulation layer TFEL and may increase an encapsulation effect of the lower inorganic encapsulation layers TL1, TL2, and TL3.

The reinforcement layer TFE4 may have excellent step coverage and cover the undercut structure of the lower inorganic encapsulation layer TFE1. In other words, the reinforcement layer TFE4 may also be formed in the separation space between the lower inorganic encapsulation layer TFE1 and the second bank BN2. The reinforcement layer TFE4 may be disposed on the second side surface BN2_S2 of the second bank BN2, the second side surface BN1_S2 of the first bank BN1, and the second side surface PDL_S2 of the pixel defining layer PDL. The reinforcement layer TFE4 may be in direct contact with the second passivation layer PAS2 of the thin film transistor layer TFTL.

The reinforcement layer TFE4 may include silicon oxide, aluminum oxide, zirconium oxide, hafnium oxide, cesium oxide, iron oxide, indium oxide, molybdenum oxide, or tin oxide, but is not limited thereto.

Hereinafter, a process of fabricating a display device 10 according to an embodiment will be described with reference to other drawings.

In the descriptions of the process (method), the operations may be performed in a different order than the order shown and/or described, or the operations may be performed in different orders or at different times. Certain operations may also be left out of the process, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

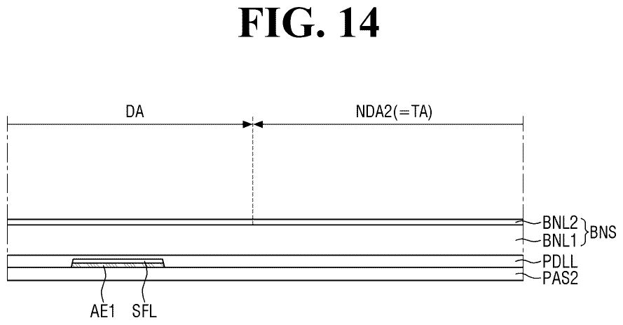

FIGS. 14 to 20 are detailed cross-sectional views sequentially illustrating a process of fabricating a display device 10 according to an embodiment. FIGS. 14 to 20 illustrate a process of forming a portion of the light emitting element layer EML and the lower inorganic encapsulation layer TFE1 at a boundary and periphery of the display area DA and the second non-display area NDA2 of the display device 10. Hereinafter, a description of a formation process of each layer in the process of fabricating the display device 10 will be omitted, and a formation order of each layer will be described.

Referring to FIG. 14, the process may include forming pixel electrodes AE1, AE2, and AE3, a sacrificial layer SFL, a pixel defining layer PDL, and a plurality of bank material layers BNL1 and BNL2 on the second passivation layer PAS2. The bank material layers BNL1 and BNL2 may be entirely formed. For example, the process may include forming the bank material layers BNL1 and BNL2 such that the bank material layers BNL1 and BNL2 completely cover the second passivation layer PAS2.

Although not illustrated in the drawings, the thin film transistor layer TFTL may be disposed on the substrate SUB, and a structure of the thin film transistor TFTL is the same as that described herein with reference to FIG. 5. Repeated descriptions thereof are omitted for brevity.

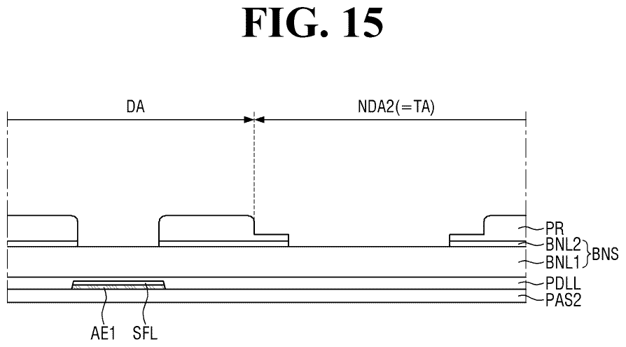

Next, referring to FIG. 15, the process may include forming a photoresist PR on the second bank material layer BNL2, and the process may include performing a first etching process of removing a portion of the second bank material layer BNL2. The photoresist PR is applied on the second bank material layer BNL2 and exposes a portion of the light emitting areas EA1, EA2, and EA3 and the second non-display area NDA2. The process may include performing a half tone exposure process. The half tone exposure process may remove portions of the second bank material layer BNL2 that are not covered by the photoresist PR, and at the same time, remove a portion of the photoresist PR on an edge of the second non-display area NDA2. Accordingly, for example, the process may include reducing a thickness of the photoresist PR in one or more areas of the photoresist PR. Based on the first etching process, the first bank material layer BNL1 respective to the light emitting areas EA1, EA2, and EA3 and the second non-display area NDA2 is exposed. A thickness of the photoresist PR at the edge of the second non-display area NDA2 (e.g., the edge of the second non-display area NDA2 adjacent the display area DA) may be smaller than a thickness of the photoresist PR at the edge of the display area DA (e.g., the edge of the display area DA adjacent the non-display area NDA2).

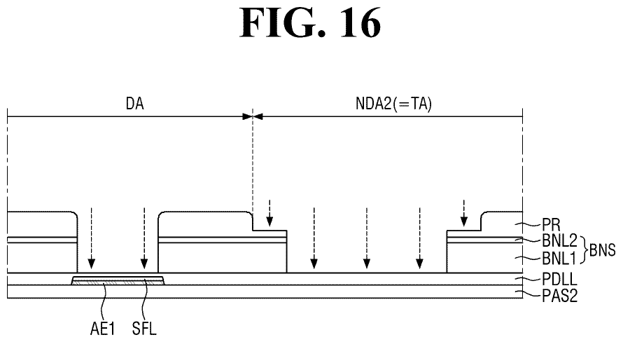

Next, referring to FIG. 16, the process may include performing a second etching process of removing portions of the first bank material layer BNL1 that are not covered with the photoresist PR. In an embodiment, the second etching process may be an anisotropic dry etching process. Based on the second etching process, a pixel defining material layer PDLL respective to the light emitting areas EA1, EA2, and EA3 and the second non-display area NDA2 is exposed.

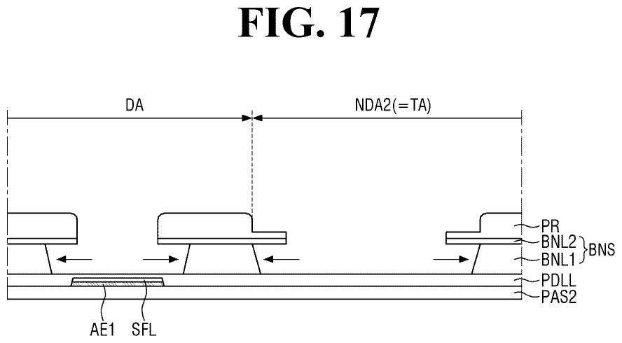

Next, referring to FIG. 17, the process may include forming an undercut structure of the first bank material layer BNL1 through a third etching process. The first bank material layer BNL1 may have a faster etching rate than the second bank material layer BNL2, and based on the third etching process, a side surface of the second bank material layer BNL2 may be formed such that the structure of the second bank material layer BNL2 protrudes further compared to a side surface of the first bank material layer BNL1. An undercut of the first bank material layer BNL1 may be formed below the second bank material layer BNL2 by the third etching process. In an embodiment, the third etching process may be isotropic wet etching. The third etching process may use an alkaline etchant.

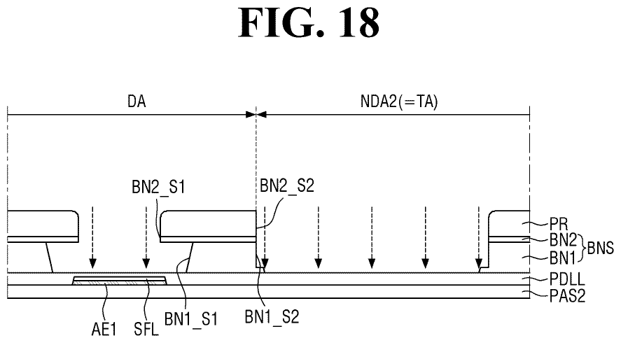

Next, referring to FIG. 18, the process may include removing the photoresist PR and the bank structure BNS (i.e., first bank BN1 and second bank BN2) of the second non-display area NDA2 through a fourth etching process. The fourth etching process may remove the photoresist PR, which is relatively thin, and the second bank material layer BNL2 and the first bank material layer BNL1 below the photoresist PR. Through an etching process, a bank structure BNS with an asymmetric cross-section may be obtained. Based on the etching process, the second side surface BN1_S2 of the first bank BN1 and the second side surface BN2_S2 of the second bank BN2 may be aligned, and the first side surface BN2_S1 of the second bank BN2 may protrude further compared to the first side surface BN1_S1 of the first bank BN1 (as labeled at FIG. 9). In an embodiment, the fourth etching process may be an anisotropic dry etching process.

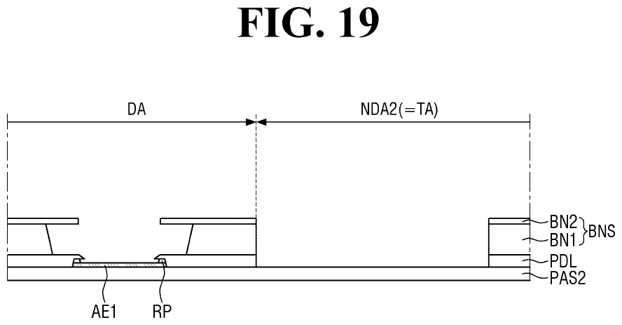

Next, referring to FIG. 19, the process may include performing a fifth etching process, which may remove the photoresist PR, remove the pixel defining layer PDL of the light emitting areas EA1, EA2, and EA3 and the second non-display area NDA2, and expose the sacrificial layer SFL. Next, the process may include removing a portion of the sacrificial layer SFL (e.g., previously illustrated at FIG. 18) and exposing the pixel electrodes AE1, AE2, and AE3 may be exposed.

The sacrificial layer SFL may protect the pixel electrodes AE1, AE2, and AE3 from plasma during the dry etching process. In some embodiments, the sacrificial layer SFL is not completely removed in the fifth etching process, and a portion of the sacrificial layer SFL may remain as some residual pattern RP between the pixel defining layer PDL and the pixel electrodes AE1, AE2, and AE3.

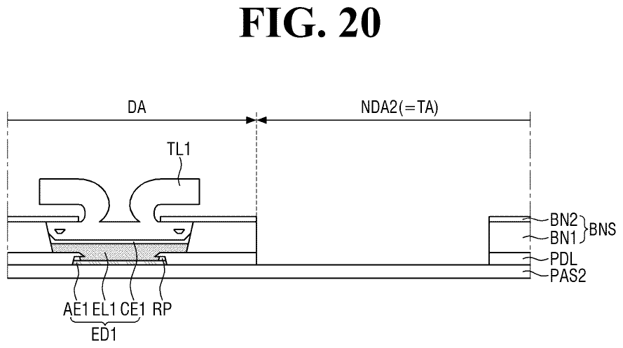

Next, as illustrated in FIG. 20, the process may include forming a first light emitting element ED1 by stacking a first light emitting layer EL1 and a first common electrode CE1 on the first pixel electrode AE1. In this case, since the first light emitting layer EL1 and the first common electrode CE1 are formed on the entire surface of the substrate SUB, the process may include (not illustrated) further forming a first light emitting pattern layer and a first electrode pattern layer including the same material as the first light emitting layer EL1 and the first common electrode CE1 on the second bank BN2.

The material deposited on the entire surface of the substrate SUB is disconnected by the protruding side surface or tip of the second bank BN2, such that the first light emitting layer EL1 in the opening and the first light emitting pattern layer on the second bank BN2 may be separated. The process may include, at the same time as forming the first common electrode CE1 on the first light emitting layer EL1, forming the first electrode pattern on the first light emitting pattern layer. In this case, for example, the process may also include sequentially forming the first light emitting pattern layer and the first electrode pattern layer in the second non-display area NDA2.

Next, the process may include forming a first inorganic material layer covering the first common electrode CE1 and the first electrode pattern layer. In an embodiment, the process may include forming the first inorganic material layer TLL1 through chemical vapor deposition (CVD). The process may include forming the first inorganic material layer TLL1 along a step (a step portion) between the first light emitting element ED1 and the bank structure BNS.

Next, the process may include removing a portion of the first inorganic material layer TLL1, and the process may include removing the first electrode pattern layer and the first light emitting pattern layer on the second bank BN2. The process may include forming a photo resist (not illustrated), which is a mask, in an area overlapping the first light emitting area EA1 and an edge area surrounding the first light emitting area EA1, and further, removing the first inorganic material layer not covered with the mask. Through such a process, the first inorganic layer TL1 remains in the area overlapping the first light emitting area EA1 and the edge area surrounding the first light emitting area EA1. The process may include removing the first light emitting pattern layer and the first electrode pattern layer disposed between the first inorganic layer TL1 and the upper surface of the second bank material layer BNL2, and further, forming an undercut structure of the first inorganic layer TL1. In this case, the process may further include removing the first light emitting pattern layer and the first electrode pattern layer of the second non-display area NDA2.

In some embodiments, as necessary, the process may include forming the fourth inorganic layer TL4 in the second non-display area NDA2 during the process of forming the first to third inorganic layers TL1, TL2, and TL3. Alternatively, or additionally, in some embodiments, as necessary, the process may include removing a portion of the thin film transistor layer TFTL from the second non-display area NDA2 by performing a laser process after forming the bank structure BNS with the asymmetric cross-section.

The embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it should be understood that the embodiments described herein are illustrative in all aspects and not restrictive.

What is claimed is:

1. A display device comprising:
a pixel electrode disposed on a substrate;
a pixel defining layer disposed on an edge of the pixel electrode;
a light emitting layer disposed on the pixel electrode;
a common electrode disposed on the light emitting layer;
a first bank disposed on the pixel defining layer and comprising a first side surface adjacent to the common electrode and a second side surface opposite to the first side surface; and
a second bank disposed on the first bank and comprising a first side surface partially overlapping the common electrode and a second side surface opposite to the first side surface,
wherein:
the first side surface of the second bank protrudes more than the first side surface of the first bank, and
the first side surface of the second bank is aligned with the second side surface of the first bank.

2. The display device of claim 1, wherein:
the pixel defining layer comprises a first side surface and a second side surface opposite to the first side surface,
the first side surface of the pixel defining layer protrudes more than the first side surface of the first bank, and
the second side surface of the pixel defining layer is aligned with the second side surface of the first bank.

3. The display device of claim 1, wherein:
the substrate comprises a light transmitting area and a display area surrounding the light transmitting area, wherein the display area comprises a light emitting area,
the first side surface of the second bank faces the light emitting area, and
the second side surface of the second bank faces the light transmitting area.

4. The display device of claim 3, further comprising a thin film transistor layer disposed between the pixel electrode and the substrate,
wherein the thin film transistor layer is exposed in the light transmitting area.

5. The display device of claim 4, further comprising a thin film encapsulation layer disposed on the thin film transistor layer, the second bank, and the common electrode.

6. The display device of claim 5, wherein the thin film encapsulation layer is in contact with the thin film transistor layer.

7. The display device of claim 5, wherein:
the thin film encapsulation layer comprises:
a lower inorganic encapsulation layer disposed on the common electrode; and
an organic encapsulation layer disposed on the lower inorganic encapsulation layer, and
the organic encapsulation layer is in contact with the thin film transistor layer in the light transmitting area.

8. The display device of claim 5, wherein:
the thin film transistor layer comprises a buffer layer, a gate insulating layer, an interlayer insulating layer, and a passivation layer sequentially disposed on the substrate, and
the thin film encapsulation layer is in contact with the passivation layer and the interlayer insulating layer.

9. The display device of claim 5, wherein the thin film encapsulation layer comprises:
a lower inorganic encapsulation layer disposed on the common electrode;
a reinforcement layer disposed on the lower inorganic encapsulation layer, the second bank, and the thin film transistor layer; and
an organic encapsulation layer disposed on the reinforcement layer.

10. The display device of claim 4, further comprising:
a first inorganic layer disposed on the common electrode and the first side surface of the first bank; and
a second inorganic layer disposed on the second side surface of the first bank and the thin film transistor layer.

11. The display device of claim 10, wherein the first inorganic layer and the second inorganic layer are spaced apart from an upper surface of the second bank.

12. The display device of claim 3, further comprising an optical device overlapping the light transmitting area.

13. The display device of claim 1, wherein the common electrode is in contact with the first side surface of the first bank.

14. A display device comprising:
a substrate comprising a light transmitting area and a display area surrounding the light transmitting area, wherein the display area comprises a light emitting area;
a thin film transistor layer disposed on the substrate;
a light emitting element disposed on the thin film transistor layer in the light emitting area;
a first bank surrounding the light emitting element disposed on the thin film transistor layer and comprising a first side surface facing the light emitting area and a second side surface facing the light transmitting area; and
a second bank disposed on the first bank and comprising a first side surface facing the light emitting area and a second side surface facing the light transmitting area,
wherein the first side surface of the second bank protrudes more than the first side surface of the first bank, and
the second side surface of the second bank is aligned with the second side surface of the first bank.

15. The display device of claim 14, wherein the first bank and the second bank overlap the display area and do not overlap the light transmitting area.

16. The display device of claim 14, wherein:
the light emitting element comprises a pixel electrode, a light emitting layer, and a common electrode sequentially disposed on the thin film transistor layer, and
an end of the common electrode is in contact with the first side surface of the first bank.

17. A method of fabricating a display device, the method comprising:
forming a pixel electrode on a substrate;
forming a sacrificial layer on the pixel electrode;
forming a pixel defining material layer on the sacrificial layer and the substrate;
forming a first bank material layer on the pixel defining material layer;
forming a second bank material layer on the first bank material layer;
forming a photoresist on the second bank material layer; and
reducing a thickness of the photoresist in some areas of the photoresist.

18. The method of claim 17, wherein the reducing of the thickness of the photoresist in some areas comprises:
using performing a half tone exposure process, wherein a portion of the second bank material layer not covered with the photoresist is etched based on performing the half tone exposure process.

19. The method of claim 17, further comprising:
etching a portion of the first bank material layer not covered with the photoresist; and
etching a side surface of the first bank material layer, wherein etching the side surface of the first bank material layer exposes a lower surface of the second bank material layer.

20. The method of claim 19, further comprising removing some portions of the second bank material layer and some portions of the first bank material layer such that a side surface of the second bank material layer and the side surface of the first bank material layer are aligned.
